(19) United States
(12) Patent Application Publication
(10) Pub. No.: US 2012/0086443 A1
(43) Pub. Date: Apr. 12, 2012

(54) Generator Operation Monitoring

(76) Inventor: Michael L. Bazzone, Delmont, PA (US)

(21) Appl. No.: 13/175,264

(22) Filed: Jul. 1, 2011

Related U.S. Application Data
(63) Continuation-in-part of application No. 12/900,556, filed on Oct. 8, 2010, now Pat. No. 8,098,967.
Application No. 12/900,556 is a continuation-in-part of application No. 12/900,678, filed on Oct. 8, 2010.

(51) Int. Cl. G01J 1/04; G01R 33/02; G01B 11/16

(52) U.S. Cl. 324/244.1; 356/32; 250/227.14

(57) ABSTRACT

A fiber optic strain and temperature sensor is disclosed. The fiber can directly measure strain and temperature or the fiber can be coated with a magnetostrictive coating to measure magnetic flux, or coated with a hydroscopic coating to measure humidity or moisture content. The optical fiber sensors can be embedded in different locations in a generator to provide real time measurement of operating conditions.

### CROSS REFERENCE TO RELATED APPLICATIONS/PRIORITY CLAIM

The present application is a continuation-in-part of U.S. patent application Ser. No. 12/900,556, filed on Oct. 8, 2010, the entirety of which is hereby incorporated by reference into the present application. In addition, the present application is a continuation-in-part of U.S. patent application Ser. No. 12/900,678, filed on Oct. 8, 2010, the entirety of which is hereby incorporated by reference into the present application.

### BACKGROUND

Electric generators, such as those used in the power generation industry, essentially comprise a rotor and a stator. The rotor is wound with conductors to form a field winding. The stator is wound with conductors to form a stator winding. The field winding is supplied with an excitation current in order to create a magnetic field on the rotor. When the rotor spins inside the stator, electric power is induced in the stator winding. By nature, all components are subject to a combination of heat, vibration, electrical fields, magnetic fields, and rotor components also experience high centrifugal forces.

In order to ensure safe and efficient operation of an electric generator, operating characteristics of the generator may be monitored using a number of different instruments located throughout the generator. Monitored characteristics may comprise, by way of example, vibration, temperature, voltage and current. Conventional metal conductor-based sensors for monitoring such characteristics may be unsuitable due to the harsh operating environment within the generator, lack of space necessary to locate such instrumentation on the generator component(s) of interest, or interference due to high magnetic and electric fields. Sensors and systems that address these limitations are therefore desirable.

### FIGURES

The novel features of the various embodiments are set forth with particularity in the appended claims. The described embodiments, however, both as to organization and methods of operation, may be best understood by reference to the following description, taken in conjunction with the accompanying drawings in which:

FIG. 2 illustrates a fiber optic flux probe sensor according to one embodiment;

FIG. 4 illustrates operation of a fiber optic flux probe sensor according to one embodiment;

FIG. 6 illustrates a graphical relationship between a frequency shift signal and an applied magnetic field according to one embodiment;

FIG. 8 illustrates detection of frequency shift signal according to one embodiment;

FIG. 10 illustrates a fiber optic flux probe sensor system for monitoring the rotor winding insulation according to one embodiment;

FIG. 12 illustrates magnetic flux waveforms detected by a fiber optic flux probe sensor system according to one embodiment;

FIG. 14 illustrates a optic sensor according to one embodiment;

FIG. 16 illustrates a fiber optic wedge tightness sensor array embedded inside elastic media according to one embodiment;

FIG. 18 illustrates operation of a fiber optic wedge tightness sensor according to one embodiment;

FIG. 20 illustrates a graphical relationship between axial strain applied on a fiber optic sensor, frequency shift and tightness according to one embodiment;

FIG. 22 illustrates tightness changes in a wedge plate over time according to one embodiment;

FIG. 24 illustrates functions used in a computer user interface program for wedge tightness monitoring according to one embodiment;

FIG. 26 illustrates a fiber optic wedge tightness sensor system according to one embodiment;

FIG. 28 illustrates a fiber optic wedge tightness sensor system for monitoring tightness variations in multiple wedge plates in the stator according to one embodiment;

FIG. 30 illustrates a fiber optic wedge tightness sensor for monitoring tightness variations showing wedges, ripple spring and filler according to one embodiment;

FIG. 32 illustrates functions used in a computer user interface program for core temperature monitoring according to one embodiment;

FIG. 34 illustrates a fiber optic core temperature sensor system for monitoring temperature variations in multiple cores in the stator according to one embodiment;

FIG. 36 illustrates a fiber washer with an embedded fiber optic sensor as a fiber optic through bolt sensor according to one embodiment;

FIG. 38 illustrates a fiber optic through bolt sensor array according to one embodiment;

FIG. 40 illustrates a graphical relationship between applied stress on a fiber washer and frequency shift according to one embodiment;

FIG. 42 illustrates a fiber optic through bolt sensor system according to one embodiment;

FIG. 44 illustrates a fiber optic parallel ring assembly sensor array according to one embodiment;

FIG. 46 illustrates a fiber optic parallel ring assembly sensor system according to one embodiment;

FIG. 48 illustrates frequency shift due to reed vibration according to one embodiment;

FIG. 50 illustrates frequency shift with temperature according to one embodiment;

FIG. 52 illustrates a fiber optic vibration/temperature sensor system according to one embodiment;

FIG. 54 illustrates a graphical relationship between the frequency shift and the relative humidity according to one embodiment;

FIG. 56 illustrates a graphical relationship between the frequency shift and the temperature around the sensor according to one embodiment.

### DESCRIPTION

### Temperature and Strain Measurement Technology

Optical fibers have inherent scattering which is both temperature and strain dependent. Brillouin and Rayleigh scattering properties are well documented in the technical literature. The property is continuous along the length of the fiber so an optical fiber can be used to sense strain and/or temperature anywhere along its length or along the entire length. The fiber itself is the sensor so, in theory, an unlimited number of areas can be sensed on a fiber. Current technology has a limitation of sensing areas of 2-5 cm over several km of fiber giving in the range of 20,000 discrete data points. Advances in technology can reasonable be expected to increase the sensing resolution and total fiber length.

In a Brillouin system, the Brillouin frequency shift ΔVₐ can be expressed as:

ΔVₐ=a+b Δμ∈+cΔT

Where the change in strain is Δμ∈, the change in temperature is ΔT and a, b, c are constants. Rayleigh, Raman or other scattering modes have similar relations.

The fiber can directly measure temperature and strain, or coatings or structures can be used to induce temperature or strain in the fiber. If temperature and strain variations are simultaneously occurring, the use of a second fiber, or a second path of the fiber, with one variable held constant, may be necessary to distinguish temperature and strain measurements.

### Fiber Optic Flux Probe Sensor

The winding turn insulation state in a rotor may be an important aspect to be real-time monitored for possible shorted turns arising during the operation of the rotor. Early information may be helpful when making a maintenance decision concerning when and whether the rotor might necessarily be taken out of service and reworked. Previous technology mainly utilizes an air-gap magnetic flux sensor on-line to measure the rotor slot leakage flux in the rotor. The traditional magnetic flux sensor may utilize the Hall probe or the coil as sensing elements, which are electrical in nature. These types of sensors may be connected to the data acquisition system outside of the generator with an electrical wire. The wire causes problems by providing a conductive pathway through the generator providing a possibility of arcing, signal interference and electrical hazards to personnel. As fiber optic sensing technology may provide the sensor system with immunity to electromagnetic interference, it may be possible to let the fiber optic flux probe sensors work in such a harsh environment. The fiber optic flux probe sensor proposed may use fiber-based Brillouin, Rayleigh, Raman or other scattering modes with ferrite-magnetostrictive coating that may allow for detection of the rotor slot leakage flux in the generator, more efficiently. Due to the direct relationship between rotor winding shorted turns and magnetic flux variation in the rotor, the amplitude of variation may be used as an indicator of shorted turns. By incorporating a plurality of sensor regions, variations in flux and temperature may be used to sort out the effect of the shorted turn as well as the local temperature rise.

### Description of Technology

Magnetic flux leakage inspection methods or tools can be used to locate and characterize the rotor winding where there have been previous episodes of shorted turns. In principle, as the generator operates, magnetic flux generated by the rotor winding may leak into the surrounding air or air-gap between the rotor and stator. This leakage flux is known as rotor slot leakage. If a magnetic flux sensor is put in this leakage region, the sensor may accumulate a physical parameter output related to the flux magnitude. The rotor slot leakage may be local to each rotor slot and its magnitude may be proportional to the current flowing through the turns found in the slot and therefore may be a possible indication of active shorted turns in the slot. Several types of known sensor systems employing Hall-type or coil-type or magnetic-resistance-type sensing elements to detect the rotor slot flux leakages in a generator have been developed. The corresponding software environment in the computer has been built to automatically determine the rotor winding shorted turns by analyzing detected flux waveforms.

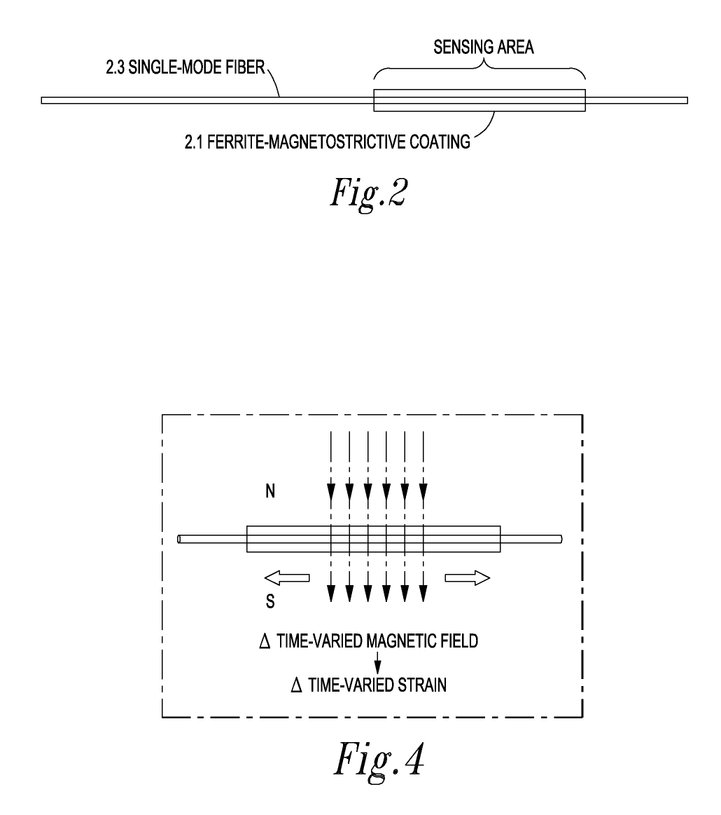

Embodiments of the optical fiber flux probe sensor may comprise a ferrite-coated sensor. The structure of this embodiment is shown in FIG. 2 in which an optical fiber may be coated with a magnetostrictive material, 2.1, such as Terfenol-D. A region of an optical fiber with a magnetostrictive coating may comprise the sensing area. Therefore it may have very high detection sensitivity and fast response speed and therefore may be very suitable for magnetic flux detections.

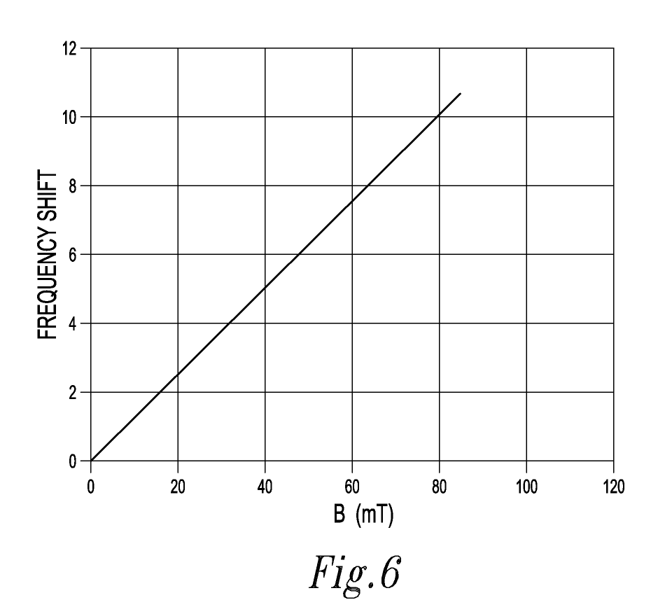

In operation principle, as illustrated in FIG. 4, the variation of applied magnetic flux through the magnetostrictive effect may affect some physical parameters of the sensor, such as Brillouin, Rayleigh, Raman or other scattering modes due to strain, through the photoelasticity of the optical fiber. As a result, it may change the frequency, amplitude or phase of the transmitted or reflected light. The change may be proportional to the applied magnetic field in intensity in an effective saturation range as illustrated in FIG. 6.

In one embodiment, Terfenol-D may be selected as a coating material for the magnetic flux sensor. It has a relatively large magnetostriction on the order of 1000 ppm for magnetizing a field of 100 mT when it operates at room temperature, free of mechanical stress. The saturation field of Terfenol-D depends on the mechanical load and increases from 100 mT to 500 mT for loading in the range 0-100 mPa. Additionally, Terfenol-D can operate efficiently at a frequency range of 0-5 kHz. It may be very suitable as a magnetostrictive coating material on the fiber sensor for the detection of rotor slot leakage flux in the generator. For example, where the rotor has 4 poles and 8 coils per pole and the rotor rotates at 60 Hz rate, the maximum frequency in detection signals generated by the rotor windings may be about 60 Hz×4×8=1.92 kHz lower than 3 kHz.

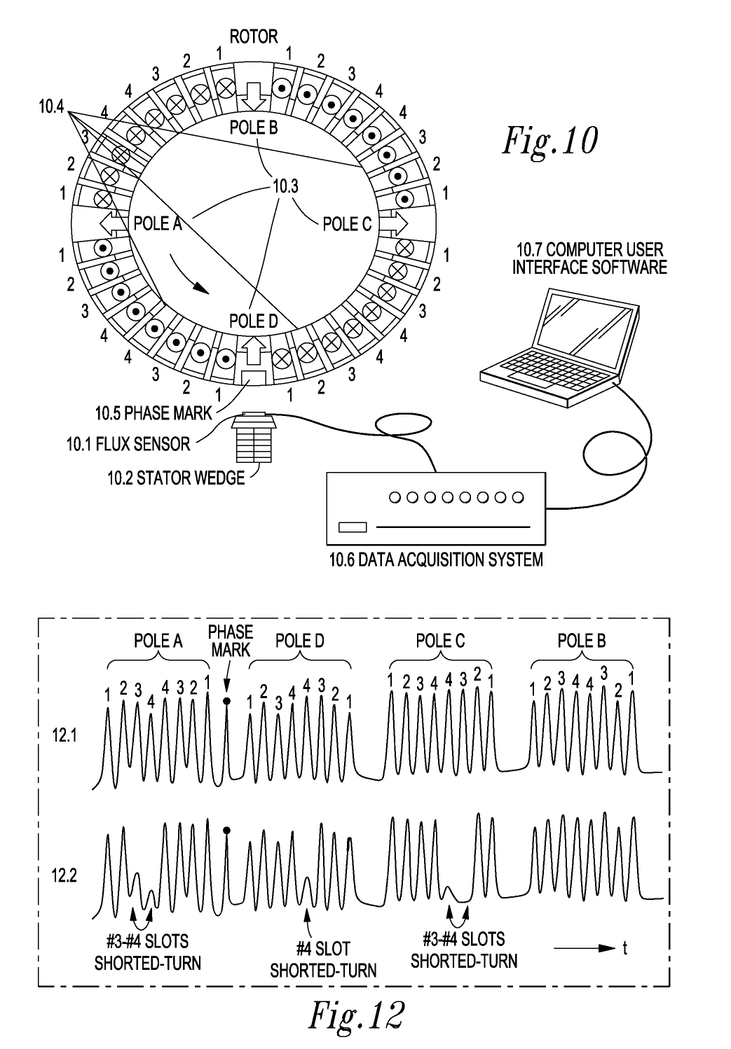

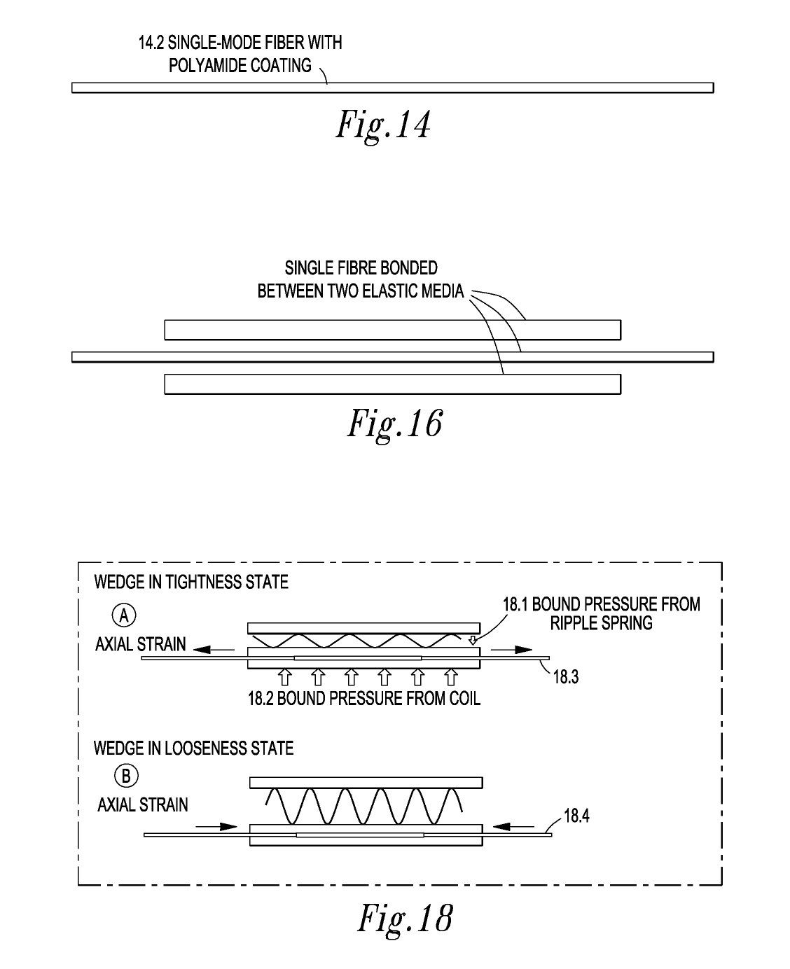

One embodiment of a sensor package is schematically illustrated in FIG. 10. The fiber flux sensor, 10.1 may be packaged into Teflon, 10.2, with fiberglass filler, 10.3, with 4-mm to 10-mm in thickness for satisfying a requirement of installing in the air-gap of the generator. In a Brillouin system, the Brillouin frequency shift ΔVₐ can be expressed as:

ΔVₐ=a+bΔμ∈+cΔT

Where the change in strain is Δμ∈, the change in temperature is ΔT and a, b, c are constants. Rayleigh, Raman or other scattering modes have similar relations.

When the ferrite-magnetostrictive coating, such as Terfenol-D coating is employed on the sensor, the magnetostriction of the coating material may affect the optical parameters of the sensor in terms of the transmittance, reflectance and frequency shift. When these optical parameters are changed, the reflected or transmitted spectrum may move as a blue shift or a red shift in spectral domain. The magnitude of frequency change may be taken as a detectable physical quantity to evaluate the magnitudes of the magnetic flux. When the magnetic flux magnitude changes with time, the detected signal may become a time-varied signal.

In one embodiment of a detection process, changes in the detected signal may be measured and then converted into an amplitude value, for example, as a voltage value. This signal processing method may comprise a tracking algorithm. In the detection of the rotor slot leakage, when the rotor rotates, each rotor slot passes over the flux sensor and the slot leakage from that slot may be detected by the fiber optic flux probe sensor and converted into a voltage signal as a flux signal, 12.1.

In the shorted-turn sensing algorithm, the premise is that the magnitude of that peak in the detected flux waveform is related to the amp-turns in the slot. Since amp-turns are directly related to the number of active turns in the slot, it is anticipated that a coil with shorted turns will display a smaller peak than a coil without shorted turns. By comparing slot peak magnitudes between poles, the number of shorted turns may be calculated for each coil in the rotor. To calculate the presence of symmetric shorted turns (same coils in all poles) may require comparison to a base set of data recorded before the development of the shorted turns.

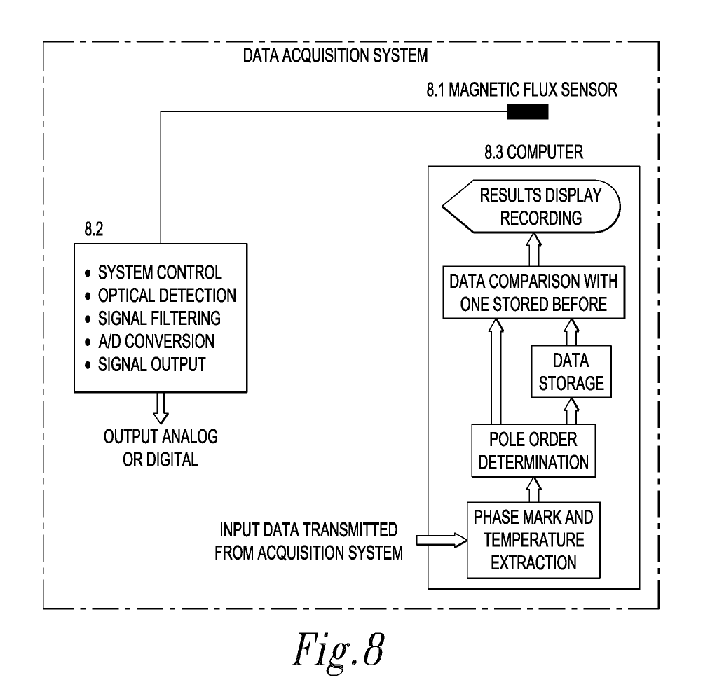

A schematic diagram of a fiber optic flux probe sensor system is illustrated in FIG. 8. The system may comprise a fiber optical flux probe sensor, 8.1, a data acquisition system, 8.2, and a computer, 8.3. The basic functions of the data acquisition system may comprise optical detection of the signal lights from the flux sensor, signal filtering, and analog-to-digital conversion and phase measurement.

In the data acquisition system, the signals received may be digitized with the analog-to-digital converter. The phase information, related to the rotor slot leakage flux, may be extracted by using a tracking algorithm as illustrated in FIG. 8. The flux sensing waveforms, in analog or digital format, may be output or transmitted to a computer for signal processing and waveform analysis. With the software in the computer, a phase mark signal embedded in flux sensing waveforms may be extracted as a signature to identify the physical pole to which a coil with shorted turns belongs.

It should be noted that the fiber optic flux probe sensor system may not only provide a basic tool for the rotor winding insulation state analysis, but may also simultaneously display the real-time temperature in the generator. This may be an important factor in determining the operating status of the rotor when the generator is in a running state.

### Example

As an application case, one embodiment of a fiber optic flux probe sensor system is schematically illustrated in FIG. 10, in which a fiber optic flux probe sensor, 10.1, may be mounted on a stator wedge, 10.2, in a position over a continuous ring of wedges. The rotor may have four poles, 10.3, and each pole may have eight slots, 10.4. The fiber optic flux probe sensor cable, 10.5, may be routed out of the stator core to connect a data acquisition system, 10.6, in which the flux waveforms may be detected, recorded and sent to a computer, 10.7, through USB connection cable. As an example, two sets of detected flux waveforms are presented in FIG. 12. In these flux waveforms, the upper trace, 12.1, with high amplitude in each flux peak, may be one case without the rotor slot shorted turns occurring, and the lower trace, 12.2, may be one case where several shorted turns occur in slots as indicated by arrows. It will be appreciated that when a slot has a shorted turn, the amp-turn in this slot may decrease and, as a result, the leakage flux may be reduced accordingly.

### Moisture Sensors

If a coating is applied to the fiber that changes physical characteristics when exposed to moisture, in the same way as a coating was used to detect magnetic flux, then it is possible to detect moisture content in the same type system that was used to detect magnetic flux.

### Fiber Optic Wedge Tightness Sensors

The stator is made of laminated steel with slots into which the individual windings are inserted. The windings are kept in place and kept from moving by a wedge system placed in the slot. When the stator wedge assembly loses its tightness, individual windings may become free to move resulting in larger vibration amplitude. The vibration originates from the electromagnetic field interaction between the rotor and the stator; it is the nature of the machine's normal operation. Excess vibration may cause rubbing and deteriorate the insulation layer between windings and eventually cause shorted turns. In many generators, tightness is maintained by inserting a ripple spring between the wedge element and fiberglass filler that directly presses against the stator coil. Tightness of the wedge assembly can be defined as a measurable physical strain in the fiberglass filler and can help to estimate the magnitude of the pressure exerted by the ripple spring. As the ripple spring becomes deformed, it introduces strain to the wedge element underneath. This strain may be measured by embedding an optical fiber inside the fiberglass filler. By properly placing the optical fiber, the vertical pressure generated by the ripple spring may be transferred into a transverse stress and an axial strain on the fiber sensor. The strain in the optical fiber may cause changes in Brillouin, Rayleigh, Raman scattering or other properties of the optical fiber. Measurement of these changes may be related to the strain in the fiber. Vibrations cause a time varying transverse stress resulting in a time varying axial strain in the fiber. In this measurement method, frequency shifts can be detected that are caused by the axial strain on the fiber which related to the tightness in the wedge assembly. The fiber itself is the sensor so, in theory, an unlimited number of areas can be sensed on a fiber. Current technology has a limitation of sensing areas of 2-5 cm over several km of fiber giving 20,000 discrete data points. Advances in technology can reasonably be expected to increase the sensing resolution.

Both static strain and varying strain can be measured allowing for measurement of both the ripple spring tightness and vibration can be measured. It may therefore be used as an automated inspection tool for monitoring the tightness in the stator coil.

The embodiment may comprise sensors with an optical fiber which may be 145 microns, for example, providing excellent adhesion so the pressure from the ripple spring may be entirely transferred into the axial strain. Polyamide is a tough polymer that may work in a harsh environment with high temperatures of up to 250° C., and like the normal fiber, may be immune to high voltages and electromagnetic interference. A similar effect can be obtained by embedding the optical fiber in fiberglass resin. Basic detection technology may be based on a measurement of the axial strain causing a frequency shift in the Brillouin, Rayleigh, Raman or other scattering modes.

The basic structure of the embodiment to monitor wedge tightness is schematically shown in FIG. 16, in which an optical fiber would be embedded inside the fiberglass filler, to form a sensing unit in the stator. In this architecture, the fiber, 18.3, is placed parallel to the coil slot in the stator and senses the entire length of the slot as illustrated in FIG. 18. In this way, the tightness state of one wedge element may be detected and identified through viewing the time signal corresponding to the wedge location by data acquisition system.

The detection principle may be explained with schematics as illustrated in FIG. 18. When the wedge assembly is tight, the pressures from the ripple spring, 18.1, and the coil, 18.2, below may generate a transverse stress in the fiberglass filler, 18.3, which may then transfer into an axial strain applied on the fiber sensor. This strain may cause the scattering frequency shift as illustrated in FIG. 24A.

Over a long period of time, as the material ages, the ripple spring gradually loses its strength, 24B. The coil may now vibrate more freely and cause damage to the insulating layer. There may be a possibility of gradual reduction of axial strain in the fiber causing the frequency shift to decrease. This information may be helpful to the maintenance engineer. When the wedge is tightened, the strain will increase; restoring to its original state with a corresponding frequency shift.

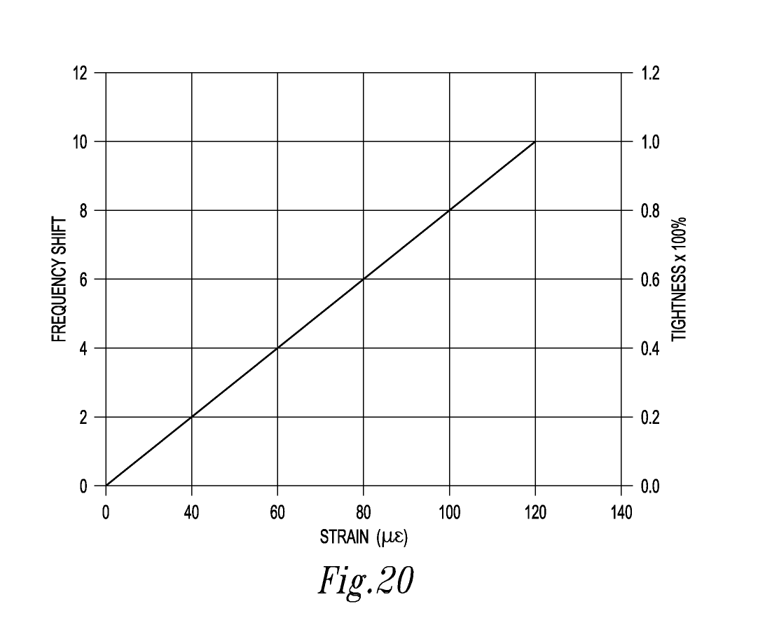

The implementation of the system and method may involve the initial set up of measurement references during the installation of the sensor arrays. After the stator coil is tightened by wedging through the ripple spring and fiberglass filler, the generator becomes ready to operate again. Recording at this time may obtain an initial state. Through continuous recordings, the change in tightness may be measured as explained in following section. The initial frequency shifts may be stored as a reference value to use later for a comparison with an updated shift value in another inspection cycle. There may be a relationship between the frequency shift and the strain applied onto the fiber sensor, as shown in FIG. 20. Generally, the tightness T_{wedge} in a normal situation, varies gradually with passed time (day or month or year), decreasing from its initial maximum value to a smaller value. When the measured T_{wedge} is lower than a designated threshold, an alarm signal may be activated.

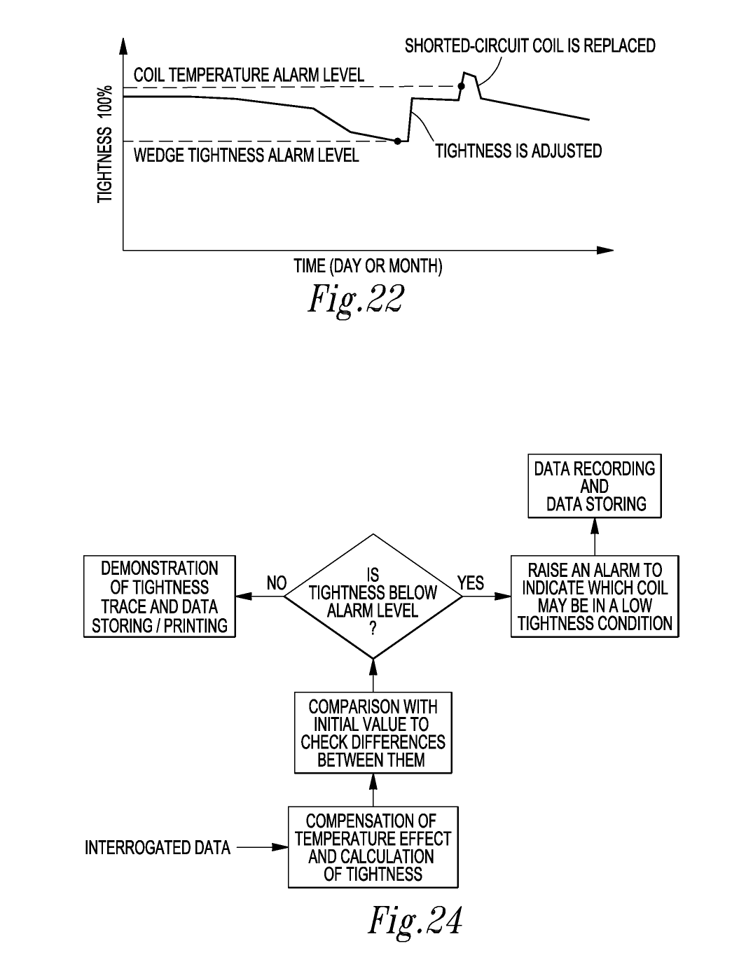

Usually, one routine inspection may be carried out in a day cycle or in a month cycle, according to the specific running situation in generator. FIG. 22 is a simulated curve of the tightness change in one wedge, which may be obtained by following the detection procedures shown in the flowchart of FIG. 24. With this trending plot of FIG. 22, one may learn about the variation in tightness in the wedge assembly over time.

### Frequency Measurement Technology

During the measurement process, the frequency changes in the scattered signal can be measured and converted into an analog value, for example, as voltages or current. In operation principle, the reflected signal is compared to the initial light and the frequency difference is measured. This frequency shift is related to the strain on the fiber.

### Data Acquisition System

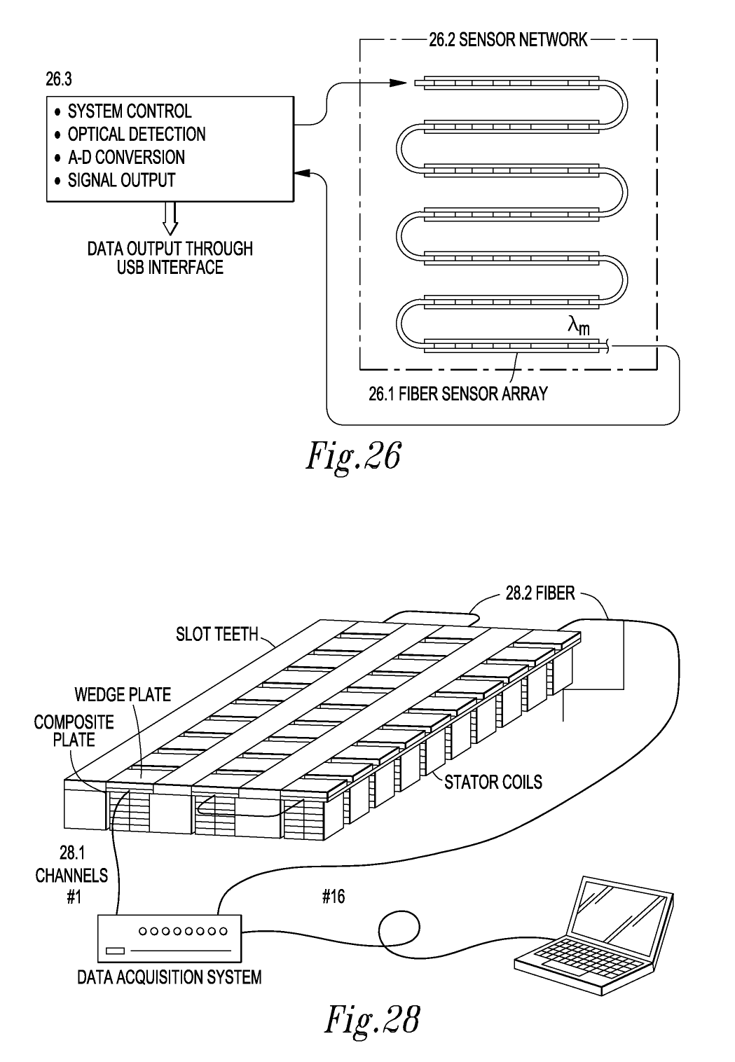

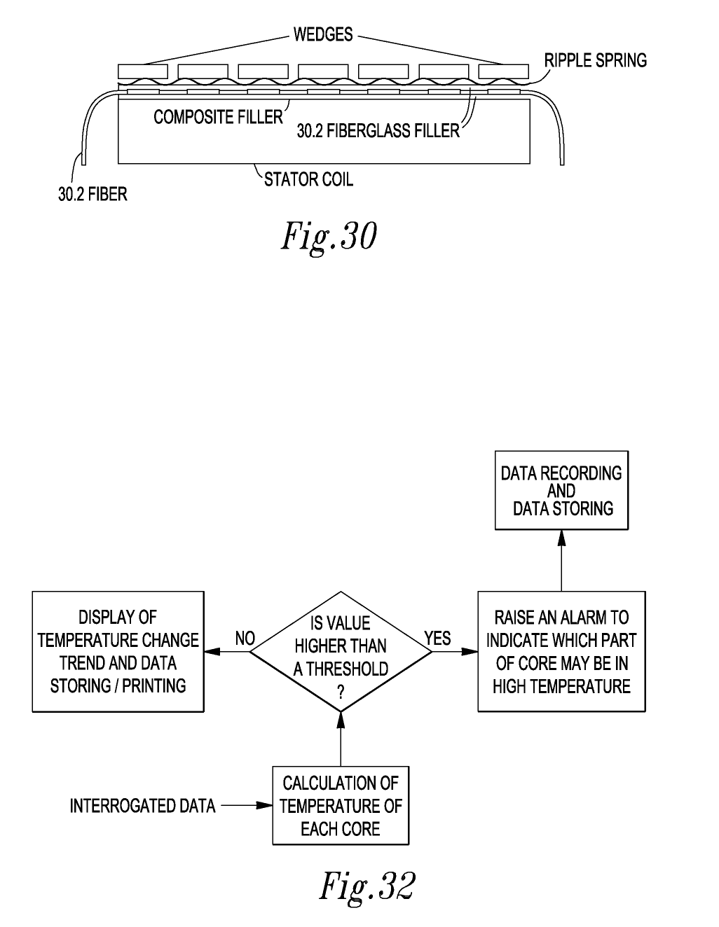

A schematic diagram of the fiber optic wedge tightness sensor system is shown in FIG. 26. The basic system (single channel) may comprise an optical fiber that may be embedded inside fiberglass filler, 26.1, and a data acquisition system. For multiple channels sensing, the data acquisition system may be able to handle multiple fibers to form a sensor network, 26.2, to manage multiple slots and wedges.

The data acquisition system may also be required to have multiple-channel detection ability, which may allow each channel to share one laser source and individually interrogate multiple different fibers.

A diagram for illustrating data processing functions in a computer user interface program is shown in FIG. 24. As illustrated, this software may be able to make adjustment to the strain measurement. When there is a tightness alert, compensation for temperature change may be taken into consideration to alleviate concerns of a false alarm.

### Example

One embodiment of a fiber optic wedge tightness sensor system is schematically shown in FIG. 28, in which a data acquisition system may simultaneously handle 16 channels, 28.1, for signal detections. Each fiber sensor array may be embedded inside a long, fiberglass filler, 28.2. The array may comprise up to 16 different fibers. Each fiber can measure tens of thousands of points so the acquisition system could return thousands of measurement points.

The detected data finally may be transmitted into the computer with the user interface software, as introduced above, where final data processing for each fiber may be performed. The calculated tightness as detection data may be recorded and stored as an inspection record or working report, according to the user's requirement.

### Fiber Optic Core Temperature Monitoring

When a short occurs within the interlaminar insulation system in the stator core, extra heat may be generated which may cause the temperature of the core to increase rapidly. Therefore, the temperature changes in the core of the stator may be monitored real-time and an alarm may be set off when the temperature in a core increases above a threshold. From Equation (2), it will be appreciated that the frequency shift of the sensor may be a function of both the strain and temperature, so the same detection principle used in monitoring the wedge tightness may also be employed to monitor the temperature of the core. The similar fiber array may be shielded in a small-size tube, (e.g., a Teflon tube) and may be placed in direct contact with the core without any additional pressure. In this way the sensor may be, materially, free of strain and may rapidly detect the temperature change in the core. Each sensor may manage a section of the core and may be registered in the data acquisition system. A slightly modified detection algorithm, originally used for monitoring the wedge tightness, may be employed to monitor the temperature of the core. The movement of the scattering frequency of a fiber may be considered from a temperature change in the corresponding core.

Both sensor and the fiber may be polyamide coated in order to provide the sensor an ability to work in a harsh environment with high temperatures of up to 250° C. Also, just like the normal fiber, the polyamide coated fiber sensor may be immune to high voltages and electromagnetic interference.

The measurement technology used for temperature detection of the core may be similar to the monitoring of the wedge tightness

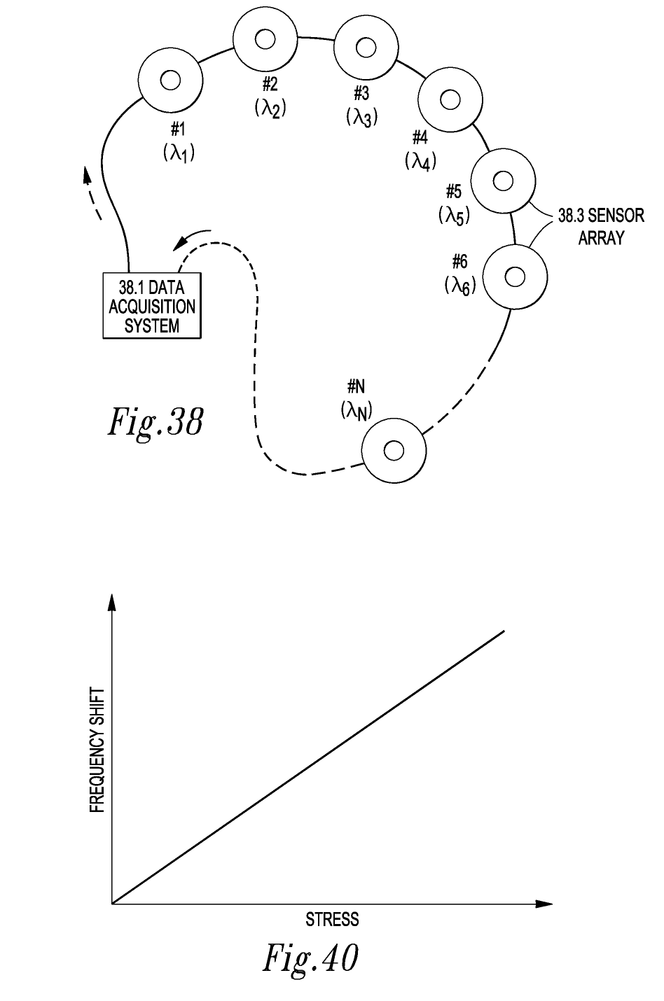

A schematic diagram of fiber optic core temperature monitoring system is shown in FIG. 38. The basic system (single channel) may comprise a fiber sensor array, 38.3, and a data acquisition system. For multiple channels sensing, the data acquisition system may be able to handle multiple fibers to form a sensor network, to manage multiple core temperatures.

A diagram for illustrating data processing functions in a computer user interface program is shown in FIG. 32. As illustrated, this software may display the temperature and change trend of each core to be monitored and set off an alarm if the temperature is higher than a threshold set previously by the user.

### Example

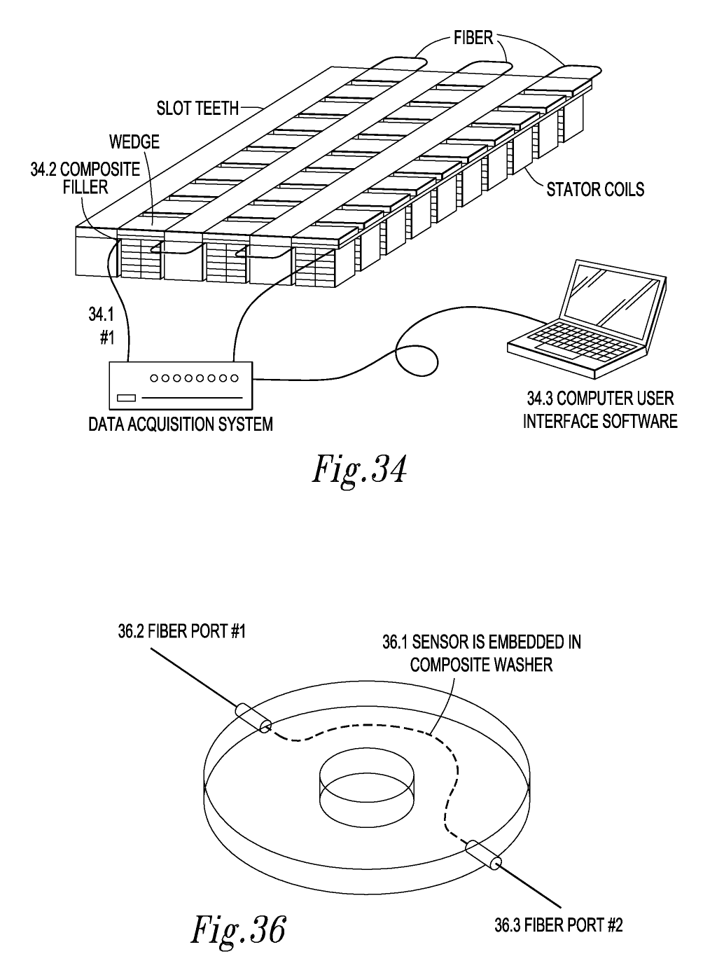

One embodiment of a fiber optic core temperature system is schematically shown in FIG. 34, in which a data acquisition system may simultaneously handle a single path of fiber or multiple fibers. Each fiber sensor array may be embedded inside a tube mounted next to the metal core of the stator. Each fiber can measure thousands of points so the acquisition system could return tens of thousands of measurement points.

The detected data finally may be transmitted into the computer with the user interface software, as introduced above, where final data processing for each fiber may be performed. The calculated temperature may be recorded and stored as an inspection record or working report, according to the user's requirement.

### Fiber Optic Through Bolt Sensors

The bolt tightness in a generator may be real-time monitored through certain detection methods. An effective detection method may be to use fiber sensor technology to measure the tightness changes according to the changes of the optical signal parameters, such as Brillouin, Rayleigh, Raman scattering or other properties of the optical fiber. This embodiment may comprise a fiberglass washer, with an embedded fiber optic sensor as a sensing element, to be used as a through bolt sensor to detect the relative torque applied on the washer by the bolt. The Brillouin, Rayleigh or Raman shift due to strain on the fiber may be used as a characteristic to determine the state of the bolt tightness.

A schematic view of the fiber optic through bolt sensor is shown in FIG. 36 in which a fiber, 36.1, as the sensing element, may be embedded into the fiberglass washer. As torque is applied to the nut, the elasticity of the washer will cause it to expand and place an axial strain on the fiber. The strain causes a frequency shift, which can then be detected. The fiber optic through bolt sensor may have two fiber ports (36.2, 36.3), which, as pictured in FIG. 38, may be utilized to connect to the data acquisition system, 38.1, or cascade with another fiber, to form a fiber optic through bolt sensor array, 38.3, that may monitor multiple bolts' tightness in one detection period. In a sensor array, each fiber optic through bolt sensor can be detected by its distance from the fiber end and the information generated by this sensor may be detected by a data acquisition system. The fiber itself is the sensor so, in theory, an unlimited number of areas can be sensed on a fiber. Current technology has a limitation of sensing areas of 2-5 cm over several km of fiber giving 20,000 discrete data points. Advances in technology can reasonably be expected to increase the sensing resolution.

A stress on the washer generated by tightening the bolt may generate a change of strain in the fiber in the fiberglass washer. This change in turn may alter the optical parameters of the fiber. These changes may be proportional to the amount of stress or torque applied on the washer, as illustrated schematically in FIG. 40.

The technology used for bolt tightness monitoring may be the same as in monitoring the wedge tightness.

Using an algorithm technology, as the state of bolt tightness changes, a frequency shift in the signal may be detected, and the change trend of the bolt tightness may also be obtained by comparing the currently measured value with the previously measured value.

### Example

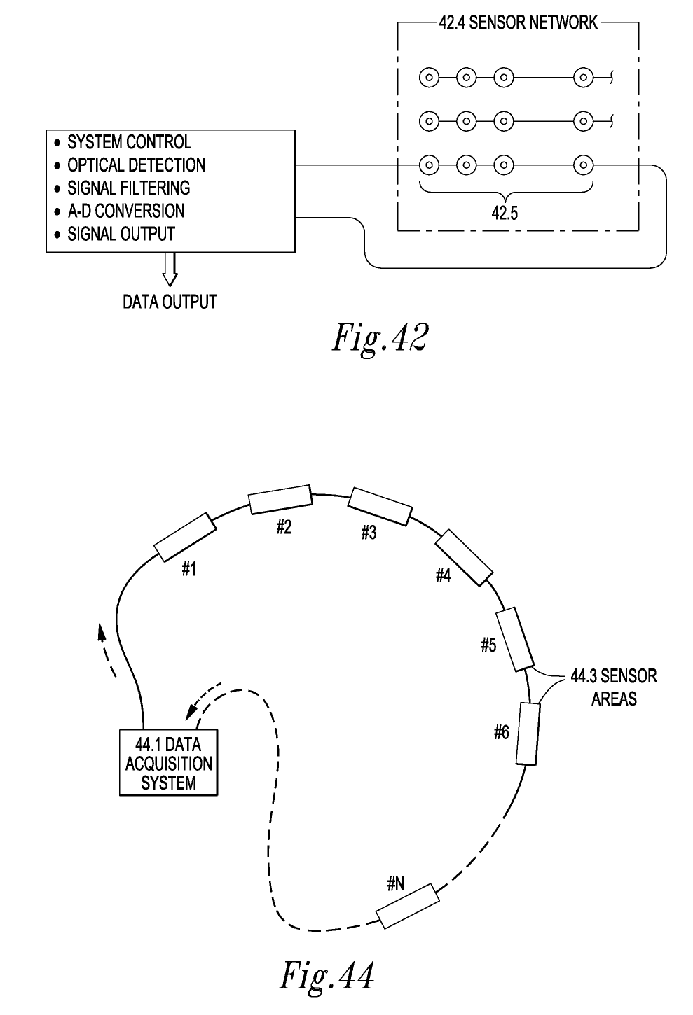

One embodiment of a fiber optic through bolt sensor system to monitor the tightening states of multiple through bolts in the generator is shown in FIG. 42. The data acquisition system may simultaneously handle N channels, and each channel may comprise m through bolt sensors, 42.5, which may form a sensor network. The detected signals in may be converted into those in digital format via an analogue-to-digital converter (ADC) and then may be fed into a micro-processing unit (MPU) for preliminary data processing. The processed data then may be transmitted to a computer. In the computer, as described in functional blocks in FIG. 24, the received data may be processed to compensate for the temperature effects. The bolt tightness change trend may be calculated and the two data sets compared: the current one and the previous one. If the bolt tightness decreases lower than the designated threshold an alarm may be raised.

### Fiber Optic Parallel Ring Assemblies Sensors

The block tightness in a generator may be real-time monitored through certain detection methods. An effective detection method may be to use fiber sensor technology to measure the tightness changes according to the changes of the optical signal parameters, such as Brillouin, Rayleigh, Raman scattering or other properties of the optical fiber. The fiber itself is the sensor so, in theory, an unlimited number of areas can be sensed on a fiber. Current technology has a limitation of sensing areas of 2-5 cm over several km of fiber giving 20,000 discrete data points. Advances in technology can reasonably be expected to increase the sensing resolution.

In this embodiment, a fiberglass block, with an embedded fiber optic sensor as a sensing element, may be used as a parallel ring assembly sensor to detect the pressure, or lack thereof, applied on the block by the bolt. The phase change in the optical detection signal may be used as a characteristic to determine the state of the block tightness.

The structure of a proposed individual sensor is schematically illustrated in FIG. 36. The fiber optic parallel ring assemblies sensor may have two fiber ports (36.1, 36.2), which, as pictured in FIG. 44, may be utilized to connect to the data acquisition system, 44.1, or cascade with another sensor, 44.3, to form a fiber optic parallel ring assemblies sensor array, that may be used to monitor multiple block tightness in one detection period.

Stress on the block, generated by tightening the bolt, may generate a change of strain of the fiber in the fiberglass block. This change may in turn alter the optical parameters as described with Equation (2),

The phase measurement technology used for block tightness monitoring may be the same as that used for monitoring the wedge tightness.

Using this measurement technology, as the state of block tightness changes, a signal variation may be detected, and the change trend of the block tightness may also be obtained by comparing the currently measured value with the previously measured value.

### Example

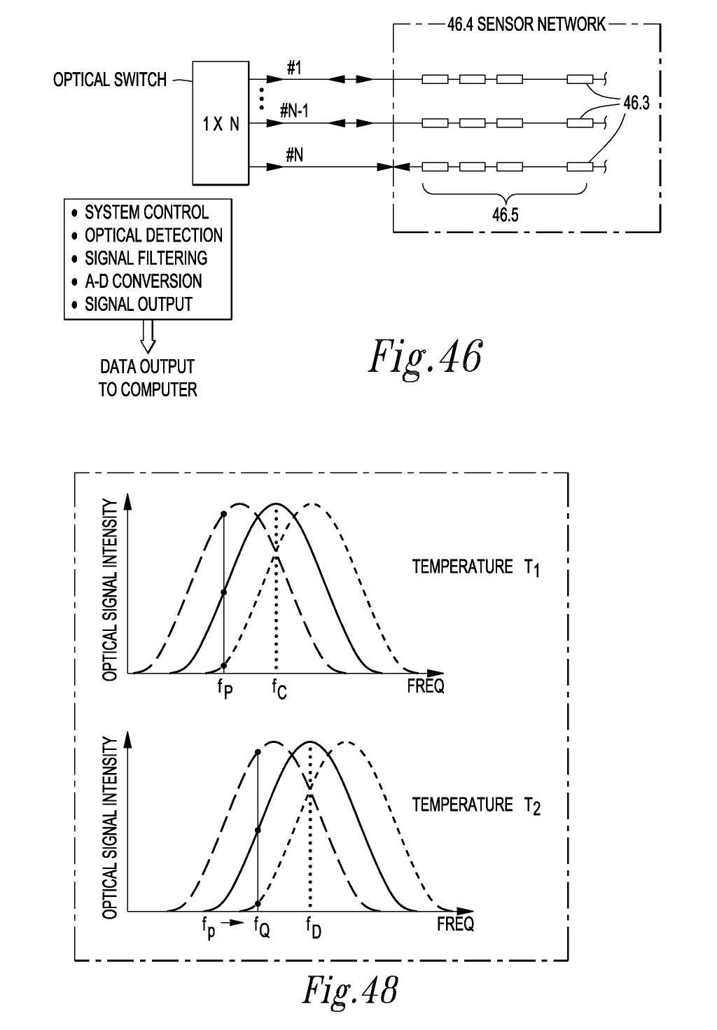

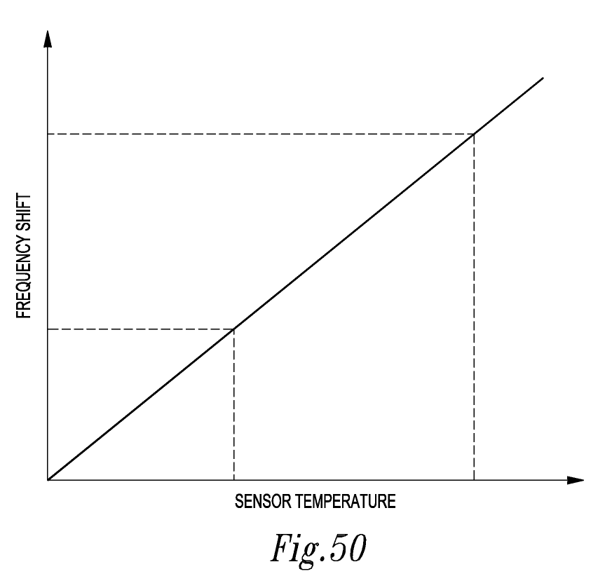

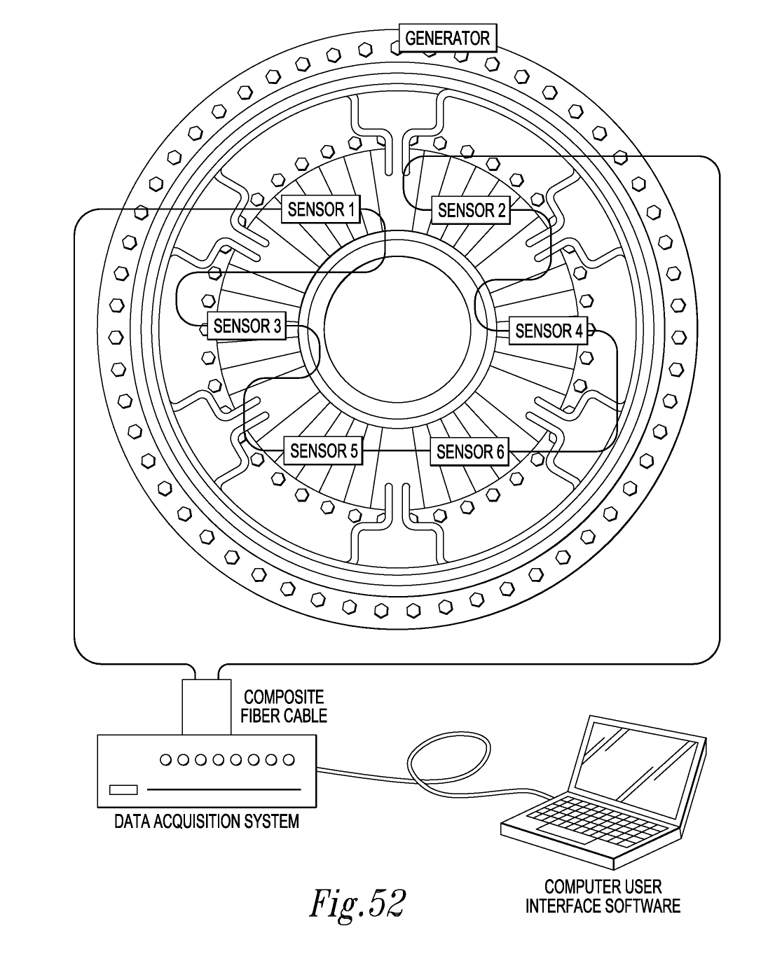

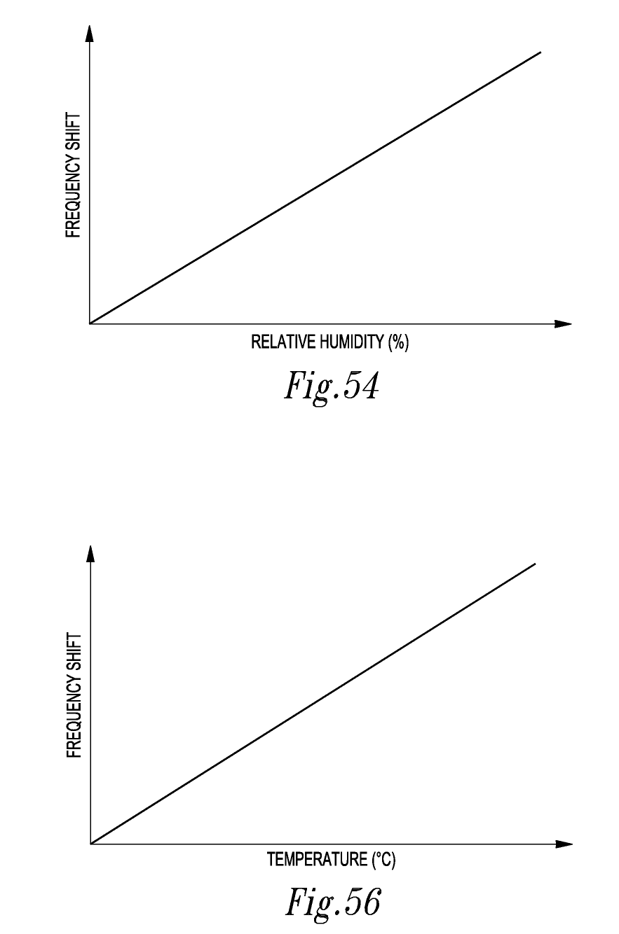

One embodiment of a fiber optic parallel ring assembly sensor system to monitor the tightening states of multiple blocks in the generator is shown in FIG. 46. The data acquisition system may simultaneously handle N channels, and each channel may comprise m parallel ring assembly sensors, 46.3, which may form a sensor network. In this way, each sensor may be accessed by the data acquisition system. The detected signals are converted into those in digital format via an analogue-to-digital converter (ADC) and then are fed into a micro-processing unit (MPU) for preliminary data processing. The processed data then are transmitted to a computer. In the computer, as described in functional blocks in FIG. 24, the received data may be processed to compensate for the temperature effects. The block tightness change trend may be calculated and the two data sets compared: the current one and the previous one. If the block tightness decreases lower than a threshold an alarm may be raised.

### Fiber Optic Parallel Ring Temperature Sensors

When the connection in the parallel ring is in poor contact, extra heat may be generated owing to an increase of the contact resistance, which may cause the temperature of the parallel ring to increase rapidly. Therefore temperature rises in the parallel rings of the stator may be monitored real-time and an alarm may be activated when the temperature in a parallel ring increases above a designated threshold. From Equation (2), it will be appreciated that the frequency of the scattered light is a function of both the strain and temperature, so the same detection principle used in monitoring the wedge tightness may also be employed to monitor the temperature of the parallel ring. A fiber may be shielded in a small-size tube (e.g., a Teflon tube) and may be placed in direct contact with parallel rings without any additional pressure. In this way the sensor may be free of strain and may rapidly detect a temperature rise in the parallel ring monitored. Each sensor may manage a part of the parallel rings and may be registered in the data acquisition system. A slightly modified detection algorithm, originally used for monitoring the wedge tightness, may be employed to monitor the temperature rise of the parallel ring. The movement of the signal in a sensor may be considered from a temperature rise in the corresponding monitoring area.

Both sensor and the fiber are polyamide coated which may provide the sensor an ability to work in harsh environments with high temperatures of up to 250° C. Also, just like the normal fiber, the polyamide coated fiber sensor may be immune to high voltages and electromagnetic interference.

The measurement technology used for temperature detection of the parallel ring may be the same as in monitoring block tightness.

A schematic diagram of fiber optic parallel ring temperature monitoring system is shown in FIG. 42. The basic system (single channel) may comprise a fiber sensor array and a data acquisition system. For multiple channels sensing, the data acquisition system may be able to handle multiple fiber sensor arrays, 42.5, to form a sensor network, 42.4, to manage multiple parallel ring temperatures.

Data processing functions in a computer user interface program may be comprised of software, this software may be able to display the temperature and change trend of each parallel ring to be monitored and set off an alarm if the temperature is higher than a threshold set previously by the user.

### Fiber Optic Coil Connection Temperature Sensors

When the connection in the coil is in poor contact, extra heat may be generated owing to an increase of the contact resistance, which may cause the temperature of the coil connection to increase rapidly. Therefore the temperature rise in the coil connection may be monitored real-time and an alarm may activate when the temperature in a coil connection increases over a designated threshold. From Equation (2), it will be appreciated that the frequency of the scattered light is a function of both the strain and temperature, so the same detection principle used in monitoring the slot temperature may also be employed to monitor the temperature of the coils. A fiber may be shielded in a small-size tube (e.g., a Teflon tube) and may be placed in direct contact with coils without any additional pressure. In this way the sensor may be free of strain and may rapidly detect a temperature rise in the parallel ring monitored. Each sensor may manage a coil connection and may be registered in the data acquisition system. A slightly modified detection algorithm originally used for monitoring the coil tightness may be employed to monitor the temperature rise of the coil connection.

Both the sensor and the fiber may be polyamide coated which may provide the sensor an ability to work in a harsh environment with high temperatures of up to 250° C. Also just like the normal fiber, the polyamide coated fiber sensor may be immune to high voltages and electromagnetic interference.

The measurement technology used for temperature detection of the coil connection may be the same as used for monitoring block tightness

A schematic diagram of fiber optic coil connection temperature monitoring system is shown in FIG. 44. The basic system (single channel) may comprise a fiber sensor and a data acquisition system. For multiple channels sensing, the data acquisition system may be able to handle multiple fiber sensors, to form a sensor network, to manage multiple coils or generators.

What is claimed is:

1. A magnetic flux sensor, comprising:
an optical fiber;
a magnetostrictive coating disposed over the desired sensory area of the fiber, the magnetostrictive coating to change an optical property of the fiber when the magnetostrictive coating is exposed to changing magnetic flux.

2. The sensor of claim 1, comprising a plurality of coated areas formed on the optical fiber.

3. The sensor of claim 1, comprising a continuous coating formed on the optical fiber.

4. The sensor of claim 1, wherein the magnetostrictive coating comprises Terfenol-D.

5. The sensor of claim 1, comprising a dielectric material disposed over each magnetostrictive coating, a shape of the dielectric material dimensioned for placement in a gap between a stator and a rotor of a generator.

6. The sensor of claim 5, wherein the dielectric material comprises fiberglass.

7. A system, comprising:
a magnetic flux sensor, comprising:
an optical fiber;
a magnetostrictive coating disposed over each fiber, the magnetostrictive coating to change an optical property of the fiber when the magnetostrictive coating is exposed to changing magnetic flux;
a laser source coupled to the optical fiber, the laser source configured to output the unique wavelength for scattering;
an optical detector coupled to the optical fiber to generate an output signal and
a processor coupled to the optical detector, the processor programmed to extract a signal based on a variation in the magnetic flux.

8. The sensor of claim 1, wherein the magnetostrictive coating comprises Terfenol-D.

9. The sensor of claim 1, comprising a dielectric material disposed over each magnetostrictive coating, a shape of the dielectric material dimensioned for placement in a gap between a stator and a rotor of a generator.

10. The sensor of claim 5, wherein the dielectric material comprises fiberglass.

11. The system of claim 8, wherein the magnetic flux sensor is disposed in a gap between a rotor and a stator of a generator to monitor magnetic flux in the gap during operation of the generator.

12. The system of claim 11, wherein the processor is programmed to determine the peak magnitude of the magnetic flux.

13. The system of claim 12, wherein the processor is programmed to determine, based on the peak magnitude of the magnetic flux, when a shorted turn is present in the rotor.

14. A strain sensor, comprising:
an optical fiber;
An elastic material to convert transverse stress into strain in the fiber

15. The sensor of claim 14, comprising a plurality structures formed on the optical fiber.

16. The sensor of claim 14, wherein the polymer coating comprises a polyamide coating.

17. The sensor of claim 14, wherein a diameter of the optical fiber comprising the polymer coating is approximately 145 microns.

18. A system, comprising:
at least one strain sensor, each strain sensor comprising:
an optical fiber;
An elastic material to convert transverse stress into strain in the fiber
a processor coupled to the strain sensor, the processor programmed to, extract a signal related to the Brillouin, Rayleigh or other scattering properties of the optical fiber.

19. The system of claim 18, comprising a plurality of strain sensors.

20. The system of claim 18, wherein the polymer coating comprises a polyamide coating.

21. The system of claim 18, wherein a diameter of the optical fiber comprising the polymer coating is approximately 145 microns.

22. The system of claim 18, comprising a first strain sensor having a plurality of sensors formed on the optical fiber, the first strain sensor contained in a filler material disposed between stator coils and a plurality of wedge elements of a generator, the filler material to convert transaxial stress into strain to the first strain sensor that is dependent on a tightness of the plurality of wedge elements.

23. A sensor to detect compressive stress generated by a fastener, the sensor comprising:
an optical fiber;
a washer of an elastic material to convert transverse stress into strain in the fiber to contain the fiber and to receive a fastener there through, the washer responsive to compressive stress applied by the fastener to change an optical property of the fiber.

24. The sensor of claim 23, comprising a plurality of sensors formed on the optical fiber.

25. The sensor of claim 23, wherein the optical fiber comprises two or more optical fiber lengths connected to define a single optical path, and wherein each of the lengths comprises a sensor formed thereon.

26. The sensor of claim 23, wherein the washer comprises fiberglass.

27. The sensor of claim 23, wherein the fastener comprises a bolt.

28. A system, comprising:
at least one sensor to detect compressive stress generated by a fastener, each sensor comprising:
an optical fiber;
a washer of an elastic material to convert transverse stress into strain in the fiber to contain the fiber and to receive a fastener there through, the washer responsive to compressive stress applied by the fastener to change an optical property of the fiber.
a laser source coupled to each sensor to input light into the optical fiber
for each sensor, an optical detector coupled to the optical fiber,
a processor coupled to the optical detector of each sensor.

29. The system of claim 28, comprising a plurality of sensors.

30. The system of claim 28, wherein the optical fiber of at least one sensor comprises two or more optical fiber lengths connected to define a single optical path,

31. The system of claim 28, wherein the laser source comprises a tunable laser diode.

32. The system of claim 28, wherein a first sensor is disposed in a generator and comprises a plurality of sensors and wherein the processor is programmed to monitor compressive stress variations of the sensors based on the tracked variation in the phases of the corresponding target fringes.

33. The system of claim 28, comprising a least one washer receiving a through bolt for providing axial compression to a plurality of laminations defining a stator core.

34. A sensor to detect compressive stress, the sensor comprising:
an optical fiber;
at least one fiber optic sensor

35. The sensor of claim 34, comprising a plurality of fiber optic sensors formed on the optical fiber.

36. The sensor of claim 34, wherein the optical fiber comprises two or more optical fiber lengths connected to define a single optical path, and wherein each of the lengths comprises a fiber optic sensor formed thereon.

37. The sensor of claim 34, wherein the housing comprises fiberglass.

38. The sensor of claim 34, wherein the housing is dimensioned for receipt by parallel ring assembly of a generator.

39. A system, comprising:
at least one sensor to detect compressive stress, each sensor comprising:
an optical fiber;
at least one fiber optic sensor

40. The system of claim 39, comprising a plurality of sensors.

41. The system of claim 39, comprising at least one sensor having a plurality of fiber optic sensors formed on the optical fiber.

42. The system of claim 39, wherein the optical fiber of at least one sensor comprises two or more optical fiber lengths connected to define a single optical path, and wherein each of the lengths comprises a fiber optic sensor formed thereon.

43. The system of claim 39, wherein the laser source comprises a tunable laser diode.

44. The system of claim 43, wherein the processor is programmed to control the laser diode to interrogate a sensor by causing the laser diode to sweep over a working wavelength of the laser diode, the working wavelength comprising the unique wavelength of each fiber optic sensor formed on the optical fiber of the sensor.

45. The system of claim 39, wherein a first sensor comprises a plurality of fiber optic sensors, and wherein the housings containing the fiber optic sensors are disposed between parallel conductor rings of a generator.

46. A moisture sensor, comprising:
an optical fiber;
a fiber optic sensor
a multiple-layer polyamide film coating disposed over the fiber optic sensor to pre-stress the sensing cavity, wherein exposure of the coating to moisture reduces the pre-stress of the sensing area to change an optical property of the fiber optic sensor

47. A system, comprising:
at least one moisture sensor, each moisture sensor comprising:
an optical fiber;
an optical fiber;
a fiber optic sensor
a multiple-layer polyamide film coating disposed over the fiber optic sensor to pre-stress the sensing cavity, wherein exposure of the coating to moisture reduces the pre-stress of the sensing area to change an optical property of the fiber optic sensor
a processor coupled to the optical detector of each moisture sensor,

48. The system of claim 47, wherein at least one moisture sensor is disposed in an oil reservoir of a generator.
